(19) United States
(12) Patent Application Publication
(10) Pub. No.: US 2010/0059753 A1
(43) Pub. Date: Mar. 11, 2010

(54) MATRIX ELECTRONIC DEVICES USING OPAQUE SUBSTRATES AND FABRICATION METHOD THEREFOR

(75) Inventors: Mark Andrews, Westmount (CA); Bell Fong, Ville St-Laurent (CA)

Correspondence Address: FULBRIGHT & JAWORSKI L.L.P., 600 CONGRESS AVE., SUITE 2400, AUSTIN, TX, 78701, US

(73) Assignee: SILK DISPLAYS, MONTREAL QUEBEC, CA (US)

(21) Appl. No.: 12/304,941

(22) PCT Filed: Jun. 15, 2007
(86) PCT No.: PCT/CA2007/001070

§ 371 Date: Oct. 1, 2009

Related U.S. Application Data
(60) Provisional application No. 60/814,077, filed on Jun. 16, 2006.

(51) Int. Cl. H01L 29/786; B32B 37/00; C23F 1/00; H01L 27/088; H01L 29/04

(52) U.S. Cl. 257/59; 156/60; 216/36; 257/E27.06; 257/E29.003; 257/E29.273

(57) ABSTRACT

A fabrication method is described for forming an electronic circuit on a flexible substrate consisting of plastic and opaque foils. Corresponding circuit structures are also described herein. The opaque substrate can be selected from a set of polymers which have the appropriate thermo-mechanical properties. The foil geometry of the opaque substrate can be selected to maximize the structural integrity on the display in the planar directions but have excellent mechanical stress distribution when bent or flexed.

### FIELD

The present invention generally relates to matrix electronic devices. More specifically, but not exclusively, the present invention is generally concerned with these devices and with fabrication methods for patterning and using a flexible substrate that can be made from a combination of polymer foil or laminate foil and a metal or opaque material mesh for making a thin film matrix electronic circuit device, including semiconductor devices supported on a flexible substrate. Such devices may be a flat panel display, for example a liquid crystal display, or other kind of large area matrix electronic devices such as a thin film data storage or memory device, an image sensing device, a thermal imaging device or a touch or fingerprint sensing array device.

### BACKGROUND

There is considerable interest in fabricating microelectronic circuits and thin film devices over large areas and on flexible substrates such as insulating polymers or metal foils, to provide, for example, curved displays or other shaped (conformal) or lightweight matrix array devices. Shaped displays are of interest for aesthetic, ergonomic design or other reasons. These include styled television and computer screens, portable display devices, children's toys and displays for vehicles where it may be desirable for the display or device to conform to the shape of the object in which it is incorporated. In some instances, the device may be permanently formed by molding, for example, into the required shape. In other cases, the device may be sufficiently flexible that it can be reversibly folded or rolled up into a compact form for space saving in portable products. N. D. Young et al. describe in a paper entitled, “AMLCDs and Electronics on Polymer Substrates”, SID Proceedings Euro Display 1996, pages 555 to 558, examples of matrix array devices on flexible substrates and their method of fabrication. The matrix electronic thin film transistors assigned to each pixel are key elements of the liquid crystal flat panel display. The performance of the display depends on the characteristics of the thin film transistors, such as their threshold voltage. Large arrays of thin film transistors, as required to make a high-resolution display, exhibit variations in threshold voltage that often cause the drive currents of the liquid crystal flat panel display (LC-FPD) to differ for identical control voltages. These variations, in turn, cause a display to appear non-uniform.

Undesirable variations in electronic properties are often avoided by implementing the active matrix pixels directly within a solid silicon substrate instead of a transparent dielectric substrate. This approach is impractical if it is desired that the substrate material be transparent; but transparent dielectric substrates require that the transistors be built as thin film devices on top of the substrate. In addition, even if a flexible transparent substrate is used, because of the difficulties in microfabrication of matrix array electronic circuits on plastic, it is difficult to obtain a tight distribution of threshold voltages in large arrays of thin-film transistors, especially as more transistors are needed to make the luminous flux from each pixel insensitive to threshold variations. For this reason, LCD FPDs are often fabricated on a glass substrate.

As mentioned above, glass substrates are often used in the fabrication of LCDs. One major disadvantage of glass is that it is fragile. Hence, glass-based displays are not robust and tend to break upon impact. A glass substrate is also sensitive to heat, which imposes a limit on the maximum temperature that it can be exposed at during processing. Furthermore, applications which may demand some degree of conformability/flexibility in the display cannot be readily implemented with displays fabricated on glass.

In reference to flexible displays then, a typical AMLCD (Active Matrix Liquid Crystal Display) device is described in U.S. Pat. No. 5,130,829 issued on Jul. 14, 1992 to John M. Shannon and entitled “Active matrix liquid crystal display devices having a metal light shield for each switching device electrically connected to an adjacent row address conductor”. This device comprises a pair of substrates, one of which is of transparent material. An LC (Liquid Crystal) material is contained between these substrates which are uniformly spaced and sealed together around their outer perimeter. One substrate (usually the bottom substrate) supports an active matrix, thin film, electronic circuit on its inner surface. This circuit defines a row and column array of pixels that can be addressed independently. Each pixel contains at least one semiconductor switching element, typically a TFT (Thin Film Transistor), and a transparent or reflective pixel electrode. Since each pixel is located at a respective intersection between sets of row and column address lines that extend between the rows and columns of pixels, the TFT is connected between associated row and column lines and its pixel electrode. The top substrate usually supports a transparent electrode on its inner surface. This ground plane electrode is common to all pixels in the array and, in the case of a color display, there may also be an array of color filter elements. The TFTs in the matrix are normally fabricated as separate semiconductor islands of amorphous or polycrystalline silicon material or an electrically conducting plastic organic material. In general, the TFTs are defined by patterning a continuous semiconductor layer deposited over the substrate to create discrete areas of, semiconductor material arranged in a row and column matrix.

Fabricating TFTs on transparent substrates presents certain difficulties. For example, while polysilicon (poly-Si) technology is entering the market by way of smaller displays in devices including personal-digital-assistants (PDAs), cellular phones, car navigation systems, poly-Si films are typically created from amorphous silicon films deposited and then converted at high temperatures to poly-Si. The maximum temperature and the duration of such thermal treatment are constrained by the temperatures that the substrate can accommodate before it is irreversibly damaged.

Use of glass substrates generally restricts poly-Si processing to temperatures below approximately 725° C. This low temperature constraint results in poorer quality poly-Si films, which are not compatible with the fabrication of high performance devices and circuits. An alternate approach is to induce improve the crystallinity of poly-Si by laser annealing the film, using excimer lasers for example. This process results in very rapid heating of the film, effecting the crystallization without excessively heating the underlying substrate. Even though the laser annealing process improves the properties of the poly-Si, the process is more costly than conventional heating of the film. Moreover, the process is also not easily adapted for volume production of displays since every TFT must be annealed over the substrate area. This reduces the throughput for display production.

Another approach has been to build the TFT either singly or in arrays on a glass substrate, then separate the TFTs from the glass substrate and transfer them to a plastic substrate. This dry transfer approach allows the use of higher temperature semiconductor processes and materials to produce TFTs, and avoids processing the plastic substrate through the TFT process. However, separation of the TFTs from the glass substrate constitutes a problematic process. A similar dry transfer method creates silicon transistors first in the solid silicon substrate and then brings them into conformal contact with a soft polymer rubber stamp, which is used to lift off the transistors. The transistors are then transferred to a plastic sheet.

Another step in the fabrication of displays is the deposition of a gate insulator (GI) layer. In the semiconductor industry, such films are typically formed by thermal oxidation at high temperatures, i.e. above about 1000° C. to ensure high quality films. However, these high temperatures cannot be used when the substrates are made of glass. Hence, a compromise in the quality of the GI layer is typically required for devices made on glass substrate.

An example of active matrix array device in which a polymer is used as the substrate material is described in U.S. Pat. No. 5,776,803 issued on Jul. 7, 1998 to Nigel D. Young and entitled “Manufacture of electronic devices comprising thin-film circuitry on a polymer substrate”. Another example of an active matrix array device on plastic is described by E. Menard et al. in a publication entitled, “Bendable single crystal silicon thin film transistors formed by printing on plastic substrates” (E. Menard, R. G. Nuzzo and J. A. Rogers, Appl. Phys. Lett. Vol. 86, p 093507, 2005). A feature of matrix array devices of these types on plastic is that they can be curved or bent. Bending can only be done if the semiconductor TFT elements are sufficiently small compared with the bend radius so that they are not cracked or delaminated in the process. Metal data and gate lines can tolerate this kind of bending because metals are inherently more ductile. The transparent conductive electrode material, like indium tin oxide (ITO) is less tolerant to bending, but this can be improved by replacing the ITO by more elastic transparent materials. Nevertheless, stress-induced crack formation, delamination and the relative mismatch of mechanical properties between the flexible substrate and matrix array device materials requires a different solution.

In general, semiconductor processes are optimized for substrates that are round, flat, and polished, like those of silicon wafers or some glasses. Plastic substrates are not conventionally available in this format. Because of undesirable mechanical properties of plastics, techniques have been developed to keep plastic substrates flat during semiconductor manufacturing processes. For example, researchers have developed various techniques to bond a plastic substrate to a carrier such as glass, which is round and flat. While this technique addresses the problem of processing plastics with its particular mechanical characteristics, it introduces other problems. Releasing the plastic substrate from the carrier creates mechanical stresses in the plastic substrate which can destroy the devices built onto the plastic. Overall, this approach still requires the use of low temperature semiconductors and processes.

Many stress compensation schemes have been developed to overcome problems created by the different thermal expansion coefficients of organic substrate and inorganic semiconductor materials. For example, semiconductor devices can be deposited as islands on a plastic substrate (the “foil”), so that when the substrate expands and contracts the devices experience little lateral distortion. In other cases, schemes have been developed to stabilize the plastic foil against thermal planar expansion or contraction. In still other approaches, the problem of expansion and contraction is related to the absorption or evaporation of water or solvents during the microfabrication processes. These effects cause mis-registration of photomasks and ultimately a misalignment of the device features required to make an array of functional devices. In part, the effects of water and solvent can be overcome by heat treating the plastic substrates in order to return the film to its original dimensions between each application of a photomask.

Even with these special treatments of the plastic substrates, bending the film can still introduce cracks and damage the elements of the array of electronic circuit devices.

### BRIEF DESCRIPTION OF THE DRAWINGS

In the appended drawings:

FIG. 1 illustrates an hexagonal array of pixels showing location of thin film transistors;

FIG. 2 illustrates an hexagonal array of pixels showing Red (R), Green (G) and Blue (B) pixels.

FIG. 3 is a cross sectional view of one hexagonal pixel showing a metal foil substrate in conjunction with a polymer support layer; and

FIG. 4 illustrates a flow diagram for fabricating TFTs on metal foil.

### DETAILED DESCRIPTION

In accordance with an illustrative aspect of the present invention, there is provided a method of forming a flexible matrix of electronic devices comprising:

providing a flexible metal substrate;

forming an electrical insulation layer on the flexible metal substrate;

forming an array of electronic devices on the electrical insulation layer;

attaching the flexible metal substrate, including the array of electronic devices and the electrical insulation layer, to a flexible plastic substrate; and

forming a desired pattern on the flexible metal substrate.

According to another illustrative aspect of the present invention, there is provided a flexible matrix of electronic devices comprising:

a flexible plastic substrate;

a flexible metal substrate secured to the flexible plastic substrate;

an electrical insulation layer provided on the flexible metal substrate; a desired pattern being formed on both the electrical insulation layer and the flexible metal substrate; and

an electronic array provided on the insulation layer.

An object of the present invention is therefore to provide an improved matrix electronic device and a fabrication method for patterning and using a flexible substrate in view of making such a matrix electronic device.

The foregoing and other objects, advantages and features of the present invention will become more apparent upon reading of the following non-restrictive description of illustrative embodiments thereof, given by way of example only with reference to the accompanying drawings.

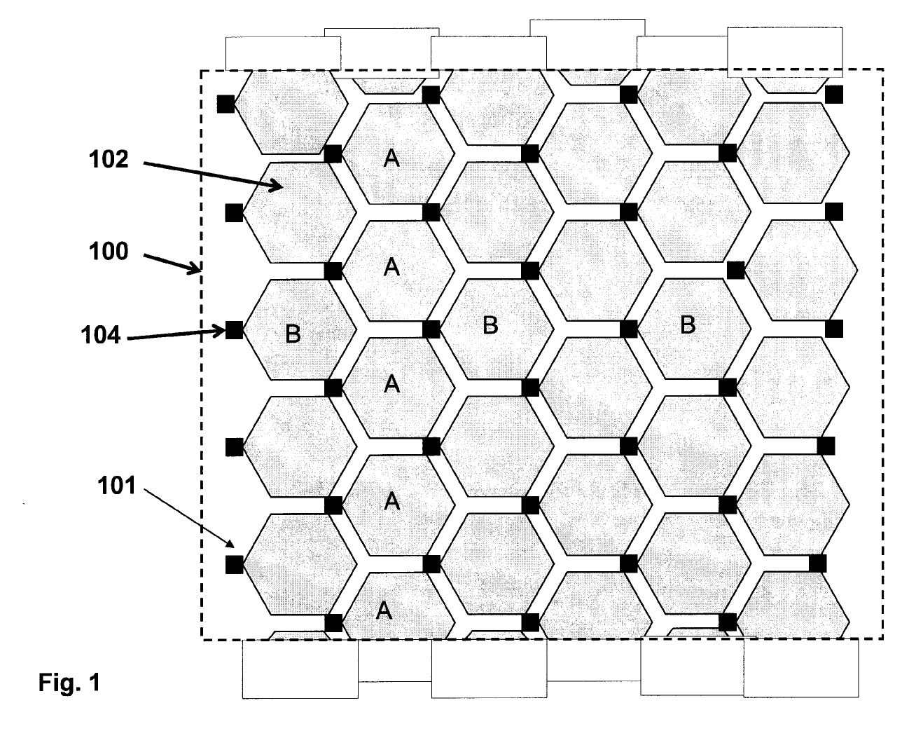

FIG. 1 is a partial top view of a flexible substrate pixel active matrix array liquid crystal display (AMLCD) 100 according to an illustrative embodiment of the present invention. The portion of display 100 delimited by the dashed line comprises a plurality of liquid crystal display pixel elements 102 being hexagonally shaped. Each liquid crystal display pixel element 102 is associated with one TFT 104 located at the intersection of three pixel elements 102 such that the TFT islands form a two-dimensional diamond lattice array.

The active matrix liquid crystal display (AMLCD) 100 therefore comprises regular rows and columns each defining an array of display pixels 101, each comprising a liquid crystal display pixel element 102 and an associated TFT 104. A column will be composed, for example of pixels A and a row will be composed, for example, of pixels B.

Of course, other device architectures could be patterned differently, depending on the geometry of the pixel element, such as a square, for example. Moreover, if a conventional AMLCD architecture is used, then there will be three TFTs associated with each pixel.

Each pixel is arranged adjacent the intersection of respective row and column address conductors (not shown for clarity). These row and column address conductors are conventionally supplied with selection (gating) and data signals, respectively, by a peripheral drive circuit (not shown) to drive the display pixels 101 and cause their display pixel elements 102 to produce desired display outputs. This pattern might be used in addressing schemes that utilize the Field Sequential Color method, for example, to achieve color mixing in the time domain.

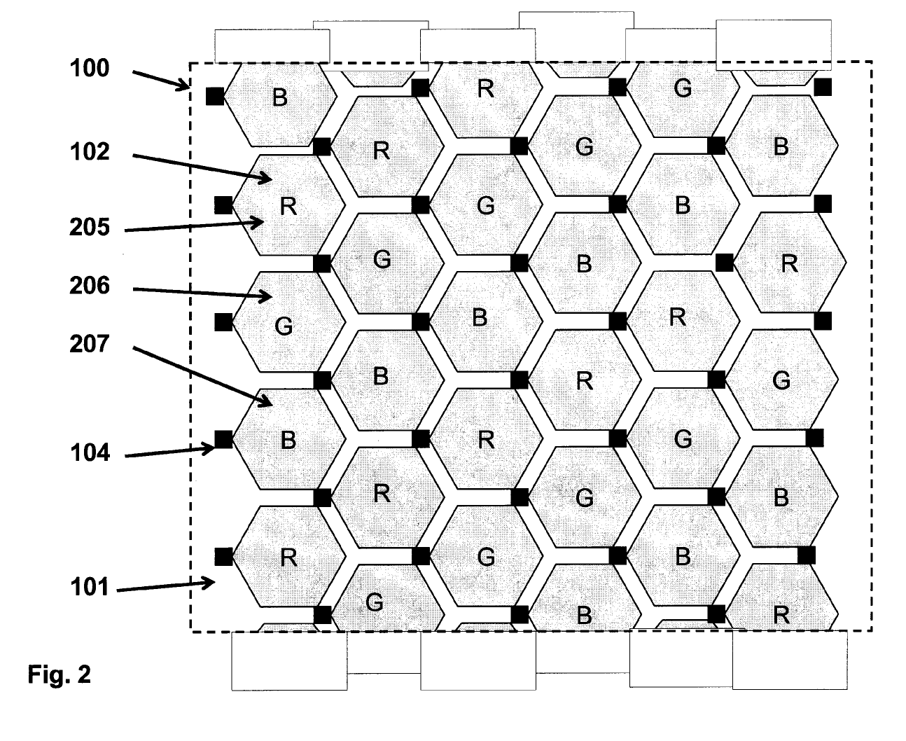

FIG. 2 is a partial top view of the flexible substrate pixel active matrix array liquid crystal display (AMLCD) 100 according to an illustrative embodiment of the present invention. The pixel grouping comprising pixel elements 205, 206 and 207 consists of a Red (R), Green (G) and Blue (B) pixel which are generally combined to constitute the body of grouped pixels that might be used to achieve color mixing in the space domain.

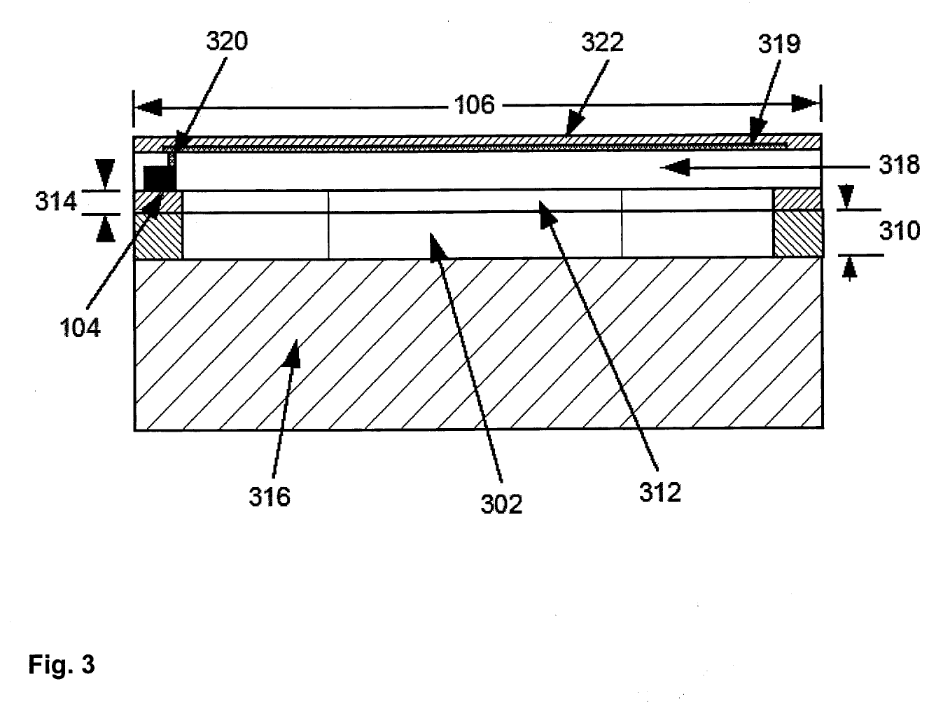

FIG. 3 is a partial cross-sectional view of the portion of display 100 of FIG. 1 illustrating a single pixel area 106 which is generally the footprint of both the display pixel element 102 and its associated TFT 104. A multitude of pixels such as 106 arranged in a matrix such as that shown in FIG. 1, form a display.

The display 100 includes a metal foil substrate 302 laminated, bonded or otherwise attached to a structural polymer foil 316. A layer of isolation material 312 is provided onto the metal foil surface 302 for each pixel area 106. At least one TFT 104 is provided for each pixel area 106, overlying the metal foil substrate 302 and separated therefrom by the isolation layer 312.

The metal foil substrate 302 is a material such as, for example, stainless steel, aluminum, titanium, Inconel alloy, Invar or Kovar. The metal foil can also be made from alloys of aluminum or titanium in order to combine reductions in the weight of the film with desirable low thermal expansion characteristics. An example of such an aluminum alloy, well known in the art, consists of aluminum with about 1% wt magnesium and/or 1% wt silicon. An example of such an titanium alloy, well known in the art, consists of titanium with about 0.2% wt aluminum and/or 0.2% wt molybdenum. Alloys of stainless steel having low thermal expansion are interesting when use in making flexible arrays of electronic devices. According to one illustrative aspect of the display, the metal foil substrate 302 has a thickness 310 in the range of about 5 to about 500 microns, advantageously in the range of about 50 to about 250 microns. One skilled in the art will understand that thinner substrates will provide for a more flexible display.

The metal foil substrate 302 is patterned to expose an array of openings, for example the hexagons 102 shown in FIG. 1. The pattern is designed to provide a deep via (hereinafter referred to as the pixel well) for light to enter. Other patterns can be created, but the hexagon is interesting since it offers significant advantages for flexibility and strength.

The pixel well is further filled and the TFT 104 is covered with a planarizing layer 318, which is overcoated with a transparent electrode 319. The transparent electrode 319 achieves electrical contact with the appropriate contact of the TFT 104 by way of a via 320 through the planarizing layer 318. Each TFT 104 is connected through data and gate lines, namely the above mentioned row and column address conductors (not shown) supplied with selection (gating) and data signals.

A black mask matrix 322 may optionally be deposited over the transparent electrode. The black mask matrix serves multiple functions, including but not limited to defining the optical boundaries of the pixel and providing an optical shield for the TFT 104.

Returning briefly to FIG. 1, it is to be noted that each TFT 104 is located at the junction between three mutually adjacent hexagonal pixel elements 102.

As mentioned hereinabove, the liquid crystal display 100 further comprises an isolation layer 312 interposed between the metal foil substrate 202 and the pixel area 106. The isolation layer 312 can be made, for example, of SiO₂ and have a thickness 314 of approximately 1 micron. More generally, the isolation layer 312 can be made of materials such as, for example, SiO₂, SiNx, SiOx, silicon oxynitride (SiON), or a combination of these materials.

The metal foil substrate 302 is supported by the structural polymer foil 316. The metal foil substrate 302 can be attached to the structural polymer foil 316 by lamination or some other film bonding process well known to those of ordinary skill in the art. The structural polymer foil 316 may be transparent to visible light and may be made of materials such as, for example, of thermoplastic films (or combinations thereof) such as poly(etheretherketone), poly(aryletherketone), poly(sulfone), poly(ethersulfone), poly(estersulfone), aromatic fluorine poly(ester), poly(etherimide), poly(etherketoneketone), poly(phenylenesulfide), cyclic olefin copolymers, polyarylates, poly(carbonate), poly(ethylenenaphthalene), and isomers thereof, poly(ethyleneterephthalate), polybutylene terephthalate, and poly-1,4-cyclohexanedimethylene terephthalate)). Other polymers include polyimides (e.g., polyacrylic imides), polymethacrylates (e.g., polyisobutyl methacrylate, polypropylmethacrylate, polyethylmethacrylate, and polymethylmethacrylate), polyacrylates (e.g., polybutylacrylate and polymethylacrylate), polystyrenes (e.g., atactic polystyrene, syndiotactic polystyrene, syndiotactic poly-alpha-methyl styrene, syndiotactic polydichlorostyrene, copolymers and blends of any of these polystyrenes), polyalkylene polymers (e.g., polyethylene, polypropylene, polybutylene, polyisobutylene, and poly(4-methyl)pentene), fluorinated polymers (e.g., perfluoroalkoxy resins, polytetrafluoroethylene, fluorinated ethylene-propylene copolymers, polyvinylidene fluoride, and polychlorotrifluoroethylene), chlorinated polymers (e.g., polyvinylidene chloride and polyvinylchloride), polyacrylonitrile, polyamides, silicone resins, epoxy resins, polyvinylacetate, polyether-amides, ionomeric resins, elastomers (e.g., polybutadiene, polyisoprene, and neoprene), polysiloxanes (including polydimethylsiloxane), and polyurethanes.

The planarizing layer 318 can be a polymer such as SU8 or other photocurable or thermocurable transparent organic material, or some other suitable material such as spin on glass, for example.

The transparent electrode 319 covering the planarizing layer 318 may be made from ITO, for example, or from other materials such as PEDOT.

The black mask matrix 322 provides a high contrast background. It can be made of any suitable material such as that supplied by Brewer Science, for example.

If desired, connections to the metal foil substrate 302 can be enabled using an additional masking step. The metal foil substrate 302 is typically covered with a one-micron thick SiO₂ insulation layer 312 to ensure optimal electrical isolation and maximum barrier properties against the diffusion of metal contaminants. Making contact to the substrate, therefore, involves etching through this relatively thick oxide film. To accomplish this etching, a masking step can be applied after the definition of poly-Si islands, with the aim of defining deep vias. Other alternatives to accomplish the connections to the metal foil substrate 302 are possible, however.

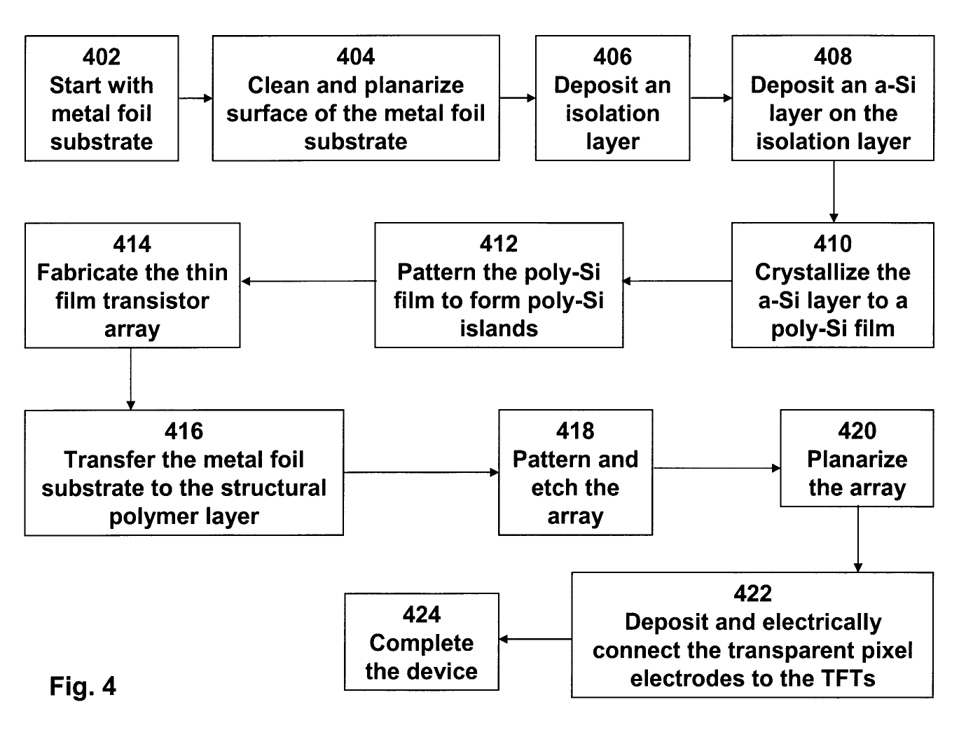

The method described below and illustrated in the flow chart of FIG. 4 is depicted as a sequence of operations identified by numbers for clarity; however, no order of the operations should be inferred from this numbering unless specifically stated. It should be understood that some of these operations may be omitted, performed in parallel, or performed without the requirement of maintaining a strict order in the sequence.

FIG. 4 is a flowchart illustrating a general TFT fabrication process according to an illustrative aspect of the present invention. The process is generally conducted as follows:

Operation 402 begins with a metal foil substrate 302. As mentioned hereinabove, the metal foil substrate 302 can be made of stainless steel, although other metallic materials such as titanium, molybdenum, aluminum, Kovar and Inconel, for example, can be used. The thickness of the metal foil substrate 302 will be in the range of about 5 to about 500 μm (microns); advantageously in the range of about 50 to about 250 μm; even more advantageously in the range of about 100 to about 200 μm.

Operation 404 consists of cleaning and planarizing the surface of the metal foil substrate 302. A number of different approaches, alone or in combination, can be used to accomplish surface planarization. For example, a Chemical-Mechanical-Polishing (CMP) step can be used to reduce the surface roughness of the metal foil substrate to better than 200 nm (average surface roughness). Alternatively, a spin-coated dielectric material (i.e. Spin-on-glass, SOG) can be used to form a uniform coating on top of the rough surface of the metal foil. The thickness of the SOG layer is in the range of about 200 to about 500 nm (nanometers). Other methods known to those of ordinary skill in the art could also be potentially used to clean and planarize the surface of the metal foil substrate.

Operation 406 consists of depositing the electrical isolation layer 312 on the metal foil substrate 302. If the metal foil substrate 302 has been planarized by CMP, the electrical isolation layer 312 is deposited directly on the metal foil substrate. If the metal foil substrate has been planarized by SOG, the electrical isolation layer is deposited on top of the SOG film. It is to be noted that the electrical isolation layer 312 also serves as diffusion barrier against diffusion of impurities from the substrate 302 to the device active layer(s) built during subsequent operations. The isolation/barrier layer 312 can be made of SiO₂ or SiOx, SiNx, SiON, or a combination of these materials or layers of these materials. The thickness of the isolation/barrier layer is in the range of about 0.5 to about 2.0 μm; advantageously from about 0.5 to about 1.5 μm; and even more advantageously from about 0.5 to about 1 μm.

In operation 408, most generally an amorphous silicon (a-Si) (which may be an hydrogenated amorphous silicon (a-Si:H)) layer is deposited on top of the barrier/isolation layer 312. The thickness of the a-Si layer is in the range of about 25 to about 150 nm; advantageously from about 25 to about 100 nm; even more advantageously from about 35 to about 60 nm. This a-Si layer could be in-situ doped or doped later with an appropriate type and amount of dopant to impose a shift in the threshold voltage of the fabricated devices towards the desired direction, i.e. towards the positive direction.

Operation 410 consists of crystallizing the a-Si layer to form a film of poly-Si material. For example, a standard solid-phase-crystallization method in a furnace or Rapid-Thermal-Annealing (RTA) can be used. The temperature range for the phase transformation is from about 600 to about 1000° C.; advantageously from about 650 to about 950° C.

In operation 412 the poly-Si film is patterned to form poly-Si islands required to form the TFTs. Techniques to perform this operation are well known to those of ordinary skill in the art.

A gate-insulation (GI) layer is formed on top of the poly-Si islands in operation 414. This operation generally requires deposition of two types of GI layers. The first layer is formed by thermal oxidation. This first layer forms the interface between the poly-Si active layer and the GI layer. High interface quality is desirable for good device characteristics. This high interface quality is achieved by the thermally-formed GI first layer. The thickness of the first layer ranges from about 10 to about 50 nm; advantageously from about 20 to about 30 nm. The second GI layer is then formed, for example, by plasma deposition, i.e. using a tetraethyl orthosilicate (TEOS) SiO₂ process. The characteristics of the second GI layer also affect the device performance, hence, the deposition process is geared towards producing a SiO₂ film that has low density of fixed charges. The thickness of the second GI layer ranges from about 40 to about 100 nm; advantageously from about 50 to about 70 nm. Alternatively, top gate transistors can be fabricated, where a thin layer of micro-crystalline silicon (μc-Si) is deposited on top of the polysilicon channel layer. The μc-Si layer functions as the source and drain and is covered by a GI layer of SiOx.

The sequence of operations 412 and 414 can be conducted in reverse order. Reversing the steps may be necessary if, for example, the high temperature to which the metal foil substrate 302 is subjected during thermal oxidation causes significant shrinkage or expansion to the metal foil substrate 302. If this happens after the metal foil substrate is initially patterned, subsequent patterns (i.e. lithography steps) may not be able to align to the first pattern (poly-Si islands) because deformation of the substrate causes mis-registration of the photomasks.

Operation 416 consists of transferring the metal foil substrate with its TFTs to the structural polymer layer 316. This operation laminates or otherwise attaches the metal foil substrate onto a plastic substrate. Lamination is achieved, for example, by interposing a contact adhesive layer between the metal and the plastic substrate using methods known in the art.

The array is patterned and etched in Step 418. The patterning is adapted to facilitate mechanical bending or flexing of the substrate and, more particularly, to encourage the substrate to flex preferentially at selected areas away from the islands of the semiconductor devices. This can be accomplished by patterning a hexagonal array as shown in FIG. 1 and placing the TFT islands at the junctions. This creates regions of flexibility where the semiconductor is not subjected to bending stress, or where the bending stress is reduced or diminished. The semiconductor devices are arranged for example in a row and column array, or a diamond array as in FIG. 1. The patterns of lines (conductors) between the hexagons may extend between, and spaced from, rows and/or columns of the semiconductor devices. Lines extending in one direction, for example between rows, would facilitate cylindrical rolling of the device. Lines extending in orthogonal directions between rows and columns would facilitate more complex bending, as required for example for spherical molding. Patterning is achieved by etching through the isolation layer 312 using standard methods. Electrochemical etching can be used, for example, to remove the metal foil in the regions patterned for the hexagons. The use of other kinds of etching can of course be contemplated.

The resulting array from step 418 is planarized in step 420. Planarization provides for a light path from the polymer substrate material through to the top surface of the metal foil, and to provide a continuous surface to complete the step contemplated in step 422. The planarizing layer 318 can be a polymer such as SU8 or some other suitable material such as Cyclotene from Dupont, for example.

Step 422 consists of depositing a transparent pixel electrode on the planarizing layer in such a way that the transparent pixel electrode is connected by a via 320 to the thin film transistor of the thin film transistor array.

A black mask material can be optionally deposited and patterned to form the black mask matrix (step not shown). The black mask matrix including hexagonal apertures corresponding to the hexagonal openings formed on the flexible metal substrate. The black mask material can be made of any suitable material such as that supplied by Brewer Science, for example.

Step 424 consists in the conventional steps to complete the device fabrication using processes that are conventional and well known to those of ordinary skill in the art. For example, a molecular alignment layer of polyimide is applied to the top surface of the bottom substrate surface of the matrix array of devices after step 422. Then spacer beads or fibers are deposited on top of the polyimide alignment layer to define a constant cell gap. A top film with a bottom transparent electrode and optionally a color filter with black mask is placed on top of the bottom flexible array of TFTs such that the transparent electrodes face one another but are not in contact. Two parallel edges of the cell are sealed with an adhesive and a liquid crystal material is drawn into the cell gap by applying a vacuum to one of the open ends. The remaining two open edges of the cell are the sealed with adhesive.

Certain components of the thin film circuitry carried on the substrate 302, such as the data conductors, gate conductors and the pixel electrodes (not shown), are required to be able to withstand some deformation of the underlying substrate when being bent. Appropriate materials, especially for comparatively long features like the address conductors, include aluminum and dilute aluminum alloys, for example, which are particularly ductile. These materials can be used in conjunction with very thin layers of molybdenum and/or chromium which, as well known to those of ordinary skill in the art of thin film electronic circuit fabrication, are beneficial in view of their ability to act as wet etch stops and as contact layers. These less ductile metals may be used in specific, localized areas such as contact regions for the active devices and formed in islands in similar manner to the semiconductor and dielectric thin film layers of the active devices. It can be envisaged that conductive materials exhibiting greater elasticity, for example conducting polymer spin-on materials or printable polymer and organic conductors and pastes can be utilized instead of metal for the address conductors.

As will be apparent to those of ordinary skill in the art, the undesirable effects of prior devices, associated with bending as discussed hereinabove can be suppressed or reduced in significance if the semiconductor materials are arranged in a periodic fashion as islands at the junctions of a grid fabricated from materials that are compatible with the production of high quality poly-Si devices. If the substrate is compliant, then patterning stiff device materials of silicon, SiOx, SiON, SiNx and so forth into an array in the suggested manner may reduce or prevent cracking and delamination. This may be especially so if the transistors are embedded at a position of neutral strain, or built up on mesas.

Accordingly, as discussed hereinabove, a non-restrictive, illustrative aspect of the present invention is concerned with a flexible matrix array device that includes a thin film matrix circuit bonded to the surface of a flexible substrate, where the matrix electronic circuit includes semiconductor devices arranged in a regular array and occupying discrete areas of the substrate which has been patterned as a grid. Moreover, selected regions of the substrate away from the areas occupied by the semiconductor devices comprise areas at which flexing of the substrate occur more readily. In order to alleviate cracking and damage to the semiconductor devices the flexible substrate carrying the active matrix circuitry is designed to cause dimensional changes resulting from bending or flexing of the substrate from its initial flat form to occur anisotropically, and more especially to encourage such changes to occur preferentially in the substrate at selected regions away from areas carrying the active semiconductor devices. Other areas of the substrate, and particularly the areas on which the TFT devices are situated, will then tend to encounter less deformation and strain upon bending or flexing of the substrate.

The flexible matrix array device may include a thin film matrix circuit bonded to the surface of a flexible substrate, where the substrate is a metal foil that allows higher processing temperatures so that higher quality semiconductor materials can be obtained, compatible with the fabrication of high performance devices and circuits. Moreover, when this metal foil is attached to a plastic substrate, it may be patterned to allow light to be transmitted so that the construction can be incorporated as part of a display, such as a liquid crystal display.

It is therefore possible to form a curved matrix array device comprising a thin film matrix circuit carried on the surface of a substrate which matrix circuit includes semiconductor devices arranged in a regular array and occupying respective, discrete, areas of the substrate, wherein the substrate comprises areas of weakness at selected regions away from the semiconductor devices and the curvature of the device is accommodated substantially by deformation of the substrate at those selected regions. Such a device may be formed, for example, by molding an initially flat device permanently into a curved shape.

In other words, a metal foil patterned with holes or openings can be used in conjunction with a plastic film as a substrate to fabricate a thin flexible composite plastic liquid crystal display. The plastic is introduced to replace the glass substrate normally used in flat panel displays. The use of a plastic film in this manner is interesting in that plastic confers qualities of ruggedness, flexibility and low weight to the display. Incorporation of the metal foil allows for a broader range of high temperature semiconductor device processes to be used in conjunction with plastics. Plastic films with metal foil backing enable a new class of displays that have non-planar geometries.

By combining a plastic film and a metal foil it is possible to improve or overcome some of the limitations of plastics when used as substrates. These limitations include, amongst others;
undesirable mechanical and thermo-mechanical characteristics as compared with glass;
low glass transition and softening temperatures (Tg) of plastics relative to high temperature semiconductor processes; and
device architectures that are not optimized for use on plastic substrates

As will easily be understood by those of ordinary skill in the art, it is interesting to use substrates that are more robust than glass, and that permit the fabrication of conformable/flexible displays. It is also interesting that displays, which are built on the above-mentioned plastic or glass substrates, are made compatible with higher processing temperatures. In that case, higher quality poly-Si materials are obtained, compatible with the fabrication of high performance devices and circuits. Displays are thus fabricated on robust opaque substrates made of metal foils or high temperature polymers and polymer composites. For example, metal foils can be used to make poly-Si TFT backplanes and high quality poly-Si TFT transistors. As mentioned hereinabove, the process involves the combination of conventional solid-phase-crystallization and thermal oxidation GI formation at high temperatures, which is permitted with the use of metal foil substrates.

Accordingly, a method has been described for forming an electronic circuit on a flexible substrate consisting of plastic and opaque foils. The opaque substrate can be selected from a set of polymers which have the appropriate thermo-mechanical properties, including glass transition temperature (Tg), melting point, softening point and liquid state properties. The foil geometry can be selected to maximize the structural integrity on the display in the planar directions while presenting an excellent mechanical stress distribution when bent or flexed. An example of this structure is a matrix made of hexagonal areas, such as a honeycomb figure. This hexagonal matrix with TFTs, embedded within a polymer laminate, as excellent mechanical characteristics, enabling flexible displays.

Although the invention has been described in particular with reference to active matrix liquid crystal display devices, it will be appreciated that it can be applied with similar advantage in matrix display devices using different display materials, for example electroluminescent materials, and in other types of matrix array devices of the kind having a regular array of matrix elements that include an active semiconductor device. Examples of the latter include large area image sensor, using photosensitive pixels comprising a photodiode or the like, active matrix touch sensing arrays, thin film data stores and memory devices. These different types of thin film electronic array devices need only use one substrate.

It is to be understood that the invention is not limited in its application to the details of construction and parts illustrated in the accompanying drawings and described hereinabove. The invention is capable of other embodiments and of being practiced in various ways. It is also to be understood that the phraseology or terminology used herein is for the purpose of description and not limitation. Hence, although the present invention has been described hereinabove by way of illustrative embodiments thereof, it can be modified, without departing from the spirit, scope and nature of the subject invention as defined in the appended claims.

What is claimed is:

1. A method of forming a flexible matrix of electronic devices comprising:
providing a flexible metal substrate;
forming an electrical insulation layer on the flexible metal substrate;
forming an array of electronic devices on the electrical insulation layer;
attaching the flexible metal substrate, including the array of electronic devices and the electrical insulation layer, to a flexible plastic substrate; and
forming a desired pattern on the flexible metal substrate.

2. The method of claim 1, wherein the flexible metal substrate includes a metal foil selected from the group consisting of stainless steel foil, aluminum foil, titanium foil, Iconel alloy foil, Invar foil, Kovar foil, aluminum alloy foil and titanium alloy foil.

3. The method of claim 2, wherein the thickness of the metal foil ranges from about 5 micrometers to about 500 micrometers.

4. The method of claim 1, wherein the flexible metal substrate includes a stainless steel foil having a low thermal expansion coefficient; the stainless steel foil consists of less than 0.5% by weight of C, less than 2% by weight of Si, 20 to about 30% by weight of Mn, and 0.005 to about 0.04% by weight of N and the balance of iron and impurities.

5. The method of claim 4, wherein the thickness of the stainless steel foil is about 5 micrometers to about 500 micrometers.

6. The method of claim 1 further comprising the step of planarizing the flexible metal surface prior to the formation of the insulating layer thereon.

7. The method of claim 6, wherein the flexible metal surface planarizing includes spinning a spin-on-glass coating onto the metal foil to a thickness in the range of about 200 nm to about 500 nm.

8. The method of claim 6, wherein the flexible metal surface planarizing includes chemical-mechanical polishing.

9. The method of claim 6, wherein the flexible metal surface planarizing includes spinning on a coating of polymer to a thickness in the range of about 200 nm to about 500 nm.

10. The method of claim 1, wherein electrical isolation layer forming step includes depositing an electrical isolation layer.

11. The method of claim 10, wherein the electrical isolation layer is selected from the group consisting of a nonstoichiometric silicon oxide SiOₓ layer, a nonstoichiometric silicon nitride (SiNx) layer, a nonstoichiometric silicon oxynitride (SiONx) layer and combinations thereof.

12. The method of claim 1, wherein the electronic array forming step includes forming a thin film transistor array on the electrical insulation layer.

13. The method of claim 12, wherein the thin film transistor array defines rows and columns of thin film transistors.

14. The method of claim 1, wherein the flexible metal substrate attaching step includes laminating the flexible metal substrate to the flexible plastic substrate.

15. The method of claim 1, wherein the flexible plastic substrate is a thermoplastic film.

16. The method of claim 15, wherein the thermoplastic film includes at least one element selected from the group consisting of poly(etheretherketone), poly(aryletherketone), poly(sulfone), poly(ethersulfone), poly(estersulfone), aromatic fluorine poly(ester), poly(etherimide), poly(etherketoneketone), poly(phenylenesulfide), cyclic olefin copolymers, polyarylates, poly(carbonate), poly(ethylenenaphthalene) and isomers thereof, poly(ethyleneterephthalate), polybutylene terephthalate, and poly-1,4-cyclohexanedimethylene terephthalate.

17. The method of claim 1, wherein the flexible plastic substrate is selected from the group consisting of polyimides (e.g., polyacrylic imides), polymethacrylates (e.g., polyisobutyl methacrylate, polypropylmethacrylate, polyethylmethacrylate, and polymethylmethacrylate), polyacrylates (e.g., polybutylacrylate and polymethylacrylate), polystyrenes (e.g., atactic polystyrene, syndiotactic polystyrene, syndiotactic poly-alpha-methyl styrene, syndiotactic polydichlorostyrene, copolymers and blends of any of these polystyrenes), polyalkylene polymers (e.g., polyethylene, polypropylene, polybutylene, polyisobutylene, and poly(4-methyl)pentene), fluorinated polymers (e.g., perfluoroalkoxy resins, polytetrafluoroethylene, fluorinated ethylene-propylene copolymers, polyvinylidene fluoride, and polychlorotrifluoroethylene), chlorinated polymers (e.g., polyvinylidene chloride and polyvinylchloride), polyacrylonitrile, polyamides, silicone resins, epoxy resins, polyvinylacetate, polyether-amides, ionomeric resins, elastomers (e.g., polybutadiene, polyisoprene, and neoprene), polysiloxanes (including polydimethylsiloxane), and polyurethanes.

18. The method of claim 12, wherein desired pattern forming step includes forming an array of hexagonal openings in the metal foil.

19. The method of claim 18, wherein the desired pattern is formed by an etching process.

20. The method of claim 18, wherein the hexagonal openings are so positioned that the thin film transistors of the transistor array are located at the junctions of the hexagonal openings in the metal foil.

21. The method of claim 18 further comprising the step of forming a planarizing layer on the flexible metal substrate once the desired pattern is formed; the planarizing layer filling the hexagonal openings in the metal foil.

22. The method of claim 21, wherein the planarizing layer includes a polymer selected from the group consisting of SU8 and Cyclotene™.

23. The method of claim 21 further comprising the step of forming transparent pixel electrodes on the planarizing layer; each transparent pixel electrode being electrically connected to a respective thin film transistor of the thin film transistor array.

24. A flexible matrix of electronic devices comprising:
a flexible plastic substrate;
a flexible metal substrate secured to the flexible plastic substrate;
an electrical insulation layer provided on the flexible metal substrate; a desired pattern being formed on both the electrical insulation layer and the flexible metal substrate; and
an electronic array provided on the insulation layer.

25. The flexible matrix of claim 24, wherein the flexible plastic substrate is a thermoplastic film.

26. The flexible matrix of claim 25, wherein the thermoplastic film includes at least one element selected from the group consisting of poly(etheretherketone), poly(aryletherketone), poly(sulfone), poly(ethersulfone), poly(estersulfone), aromatic fluorine poly(ester), poly(etherimide), poly(etherketoneketone), poly(phenylenesulfide), cyclic olefin copolymers, polyarylates, poly(carbonate), poly(ethylenenaphthalene) and isomers thereof, poly(ethyleneterephthalate), polybutylene terephthalate, and poly-1,4-cyclohexanedimethylene terephthalate.

27. The flexible matrix of claim 24, wherein the flexible plastic substrate is selected from the group consisting of polyimides (e.g., polyacrylic imides), polymethacrylates (e.g., polyisobutyl methacrylate, polypropylmethacrylate, polyethylmethacrylate, and polymethylmethacrylate), polyacrylates (e.g., polybutylacrylate and polymethylacrylate), polystyrenes (e.g., atactic polystyrene, syndiotactic polystyrene, syndiotactic poly-alpha-methyl styrene, syndiotactic polydichlorostyrene, copolymers and blends of any of these polystyrenes), polyalkylene polymers (e.g., polyethylene, polypropylene, polybutylene, polyisobutylene, and poly(4-methyl)pentene), fluorinated polymers (e.g., perfluoroalkoxy resins, polytetrafluoroethylene, fluorinated ethylene-propylene copolymers, polyvinylidene fluoride, and polychlorotrifluoroethylene), chlorinated polymers (e.g., polyvinylidene chloride and polyvinylchloride), polyacrylonitrile, polyamides, silicone resins, epoxy resins, polyvinylacetate, polyether-amides, ionomeric resins, elastomers (e.g., polybutadiene, polyisoprene, and neoprene), polysiloxanes (including polydimethylsiloxane), and polyurethanes.

28. The flexible matrix of claim 24, wherein the flexible metal substrate includes a metal foil selected from the group consisting of stainless steel foil, aluminum foil, titanium foil, Iconel alloy foil, Invar foil, Kovar foil, aluminum alloy foil and titanium alloy foil.

29. The flexible matrix of claim 28, wherein the thickness of the metal foil ranges from about 5 micrometers to about 500 micrometers.

30. The flexible matrix of claim 24, wherein the flexible metal substrate includes a stainless steel foil having a low thermal expansion coefficient; the stainless steel foil consists of less than 0.5% by weight of C, less than 2% by weight of Si, 20 to about 30% by weight of Mn, and 0.005 to about 0.04% by weight of N and the balance of iron and impurities.

31. The flexible matrix of claim 30, wherein the thickness of the stainless steel foil is about 5 micrometers to about 500 micrometers.

32. The flexible matrix of claim 24, wherein the electrical isolation layer is selected from the group consisting of a nonstoichiometric silicon oxide SiOₓ layer, a nonstoichiometric silicon nitride (SiNx) layer, a nonstoichiometric silicon oxynitride (SiONx) layer and combinations thereof.

33. The flexible matrix of claim 24, wherein the electronic array includes a thin film transistor array on the electrical insulation layer.

34. The flexible matrix of claim 33, wherein the thin film transistor array defines rows and columns of thin film transistors.

35. The flexible matrix of claim 34, wherein the desired pattern formed on both the insulation layer and the flexible metal substrate defines an array of hexagonal openings; the thin film transistors of the transistor array are located at the junctions of the hexagonal openings.

36. The flexible matrix of claim 24 further comprising a planarizing layer provided on the electronic array.

37. The flexible matrix of claim 33 further comprising transparent pixel electrodes on the planarizing layer; each transparent pixel electrode being electrically connected to a respective thin film transistor of the thin film transistor array.

38. The flexible matrix of claim 24 further comprising a black mask matrix on the transparent electrodes, the black mask matrix including hexagonal apertures corresponding to the hexagonal openings formed on the flexible metal substrate.
